(19) United States
(12) Patent Application Publication
(10) Pub. No.: US 2011/0240084 A1
(43) Pub. Date: Oct. 6, 2011

(54) SOLAR BATTERY DEVICE WITH CONNECTED PHOTOVOLTAIC CELLS

(75) Inventors: CHIH-MING LAI, Chu-Nan (TW); RONG-YIH YAN, Chu-Nan (TW)

(73) Assignee: FOXSEMICON INTEGRATED TECHNOLOGY, INC., Chu-Nan (TW)

(21) Appl. No.: 12/913,787

(22) Filed: Oct. 28, 2010

(30) Foreign Application Priority Data
Apr. 2, 2010 (TW) 99110255

(51) Int. Cl. H01L 31/05

(52) U.S. Cl. 136/244

(57) ABSTRACT

An exemplary solar battery device includes plural photovoltaic cells detachably connected together. Each photovoltaic cell includes a base and a chip unit supported by the base. The chip unit includes a first electrode at a bottom thereof and a second electrode at a top thereof. The base includes first electrical terminals and second electrical terminals, which are respectively connected with the first and second electrodes of the chip unit. The photovoltaic cells are electrically connected with each other in a selected one of the following arrangements: connection in series, connection in parallel, and connection in both series and parallel, via corresponding ones of the first and second electrical terminals.

### BACKGROUND

1. Technical Field

The present disclosure relates to solar power collection, and particularly to a solar battery device incorporating a plurality of modular photovoltaic cells.

2. Description of Related Art

A popular kind of solar power system utilizes photovoltaic cells each including a chip therein converting sunlight into electricity. As power provided by a photovoltaic cell with a single chip is often insufficient to meet actual requirements, solar batteries incorporating a plurality of chips electrically connected and encapsulated together have been developed. The chips are connected in series or parallel by wires for increased voltage or current.

Each chip forms a first electrode at a top thereof, and a second electrode at a bottom thereof. In a series connection of the chips, for each two consecutive chips, one end of the wire connects to the top of a front chip by soldering, with the opposite end of the wire connected to the bottom of an adjacent rear chip by soldering. Thus, the first electrode of the front chip is electrically connected with the second electrode of the rear chip in series. However, it is time-consuming to connect the chips. In addition, solder defects may cause separation of the wire from the chip, with resulting disconnection of the solar battery. This fault is difficult to remedy, as the chips are encapsulated together. A faulty connection or chip may cause the solar battery to completely fail, since the other remaining chips are unable to deliver stored energy.

Thus, it is desired to overcome the described limitations.

### BRIEF DESCRIPTION OF THE DRAWINGS

FIG. 1 is an exploded, isometric view of a photovoltaic cell of a solar battery device in accordance with various embodiments herein.

FIG. 2 is an exploded, isometric view of a solar battery device in accordance with a first embodiment, incorporating two photovoltaic cells of FIG. 1, with encapsulating layers of the photovoltaic cells omitted.

FIG. 3 is an assembled view of the solar battery device shown in FIG. 2.

FIG. 4 is an isometric view of a solar battery device in accordance with a second embodiment, incorporating two photovoltaic cells, with encapsulating layers of the photovoltaic cells omitted.

FIG. 5 is an isometric view of a solar battery device in accordance with a third embodiment, incorporating two photovoltaic cells of FIG. 1, with encapsulating layers of the photovoltaic cells omitted.

FIG. 6 is an isometric view of a solar battery device in accordance with a fourth embodiment, incorporating four photovoltaic cells of FIG. 1, with encapsulating layers of the photovoltaic cells omitted.

FIG. 7 is an equivalent circuit diagram of the solar battery device of FIG. 6.

FIG. 8 is an isometric view of a solar battery device in accordance with a fifth embodiment, incorporating nine photovoltaic cells of FIG. 1, with encapsulating layers of the photovoltaic cells omitted.

FIG. 9 is an equivalent circuit diagram of the solar battery device of FIG. 8.

FIG. 10 is an isometric view of a photovoltaic cell of a solar battery device in accordance with various alternative embodiments herein, but not showing an encapsulating layer thereof.

### DETAILED DESCRIPTION

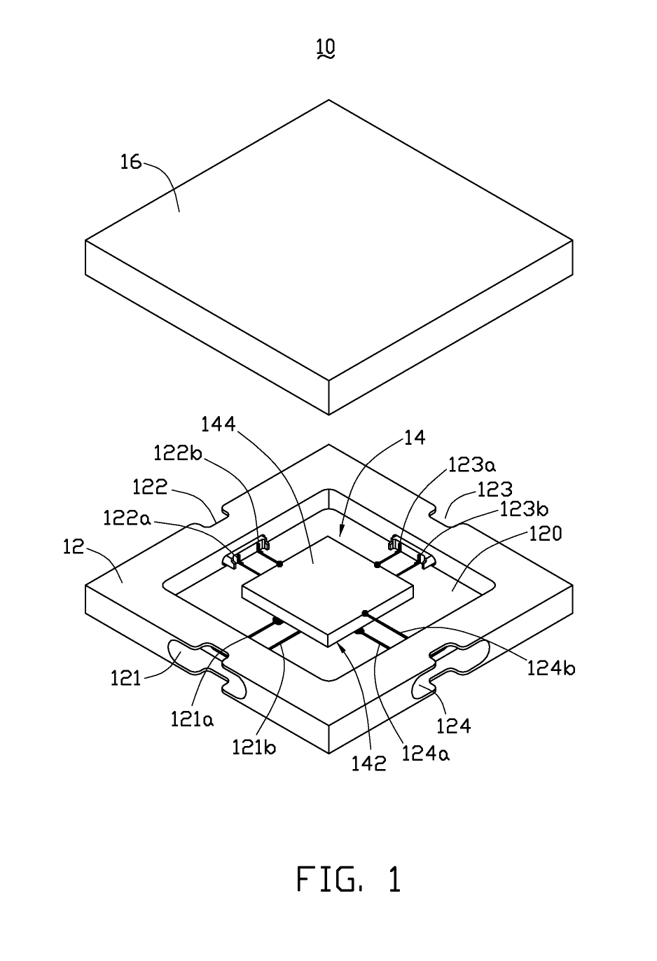

FIG. 1 shows a photovoltaic cell 10 in accordance with various embodiments of a solar battery device herein. The photovoltaic cell 10 includes a base 12, a chip unit 14 supported by the base 12, and an encapsulating layer 16 for encapsulating the chip unit 14. The encapsulating layer 16 is made of light penetrable (transparent) material. The base 12 is made of electrically insulating material. The base 12 is triangular, square, rectangular, hexagonal, rhomboid, circular, annular, or another desired shape. In this embodiment, the base 12 is square, and defines a recess 120 in a top surface thereof for receiving the chip unit 14 therein. In this embodiment, the chip unit 14 is a single chip. Alternatively, the chip unit 14 can be formed of a plurality of electrically connected chips. The chip unit 14 forms a first electrode 142 at a bottom surface thereof, and a second electrode 144 at a top surface thereof.

A plurality of electrical connectors is formed at sides of an outer periphery of the base 12. Each electrical connector includes a first electrical terminal and a second electrical terminal therein. In this embodiment, each electrical connector is in the form of a socket. The base 12 includes a pair of first and second series sockets 121, 123 at two opposite sides thereof, and a pair of first and second parallel sockets 122, 124 at another two opposite sides thereof.

A first electrical terminal 121a of the first series socket 121 is electrically connected with the first electrode 142 of the chip unit 14. A first electrical terminal 123a of the second series socket 123 is electrically connected with the second electrode 144 of the chip unit 14. A second electrical terminal 121b of the first series socket 121 is directly electrically connected with a second electrical terminal 123b of the second series socket 123. A first electrical terminal 122a and a second electrical terminal 122b of the first parallel socket 122 are respectively electrically connected with the first and second electrodes 142, 144 of the chip unit 14. A first electrical terminal 124a and a second electrical terminal 124b of the second parallel socket 124 are respectively electrically connected with the first and second electrodes 142, 144 of the chip unit 14. The first and second electrical terminals 122a, 122b of the first parallel socket 122 respectively face toward the first and second electrical terminals 124a, 124b of the second parallel socket 124.

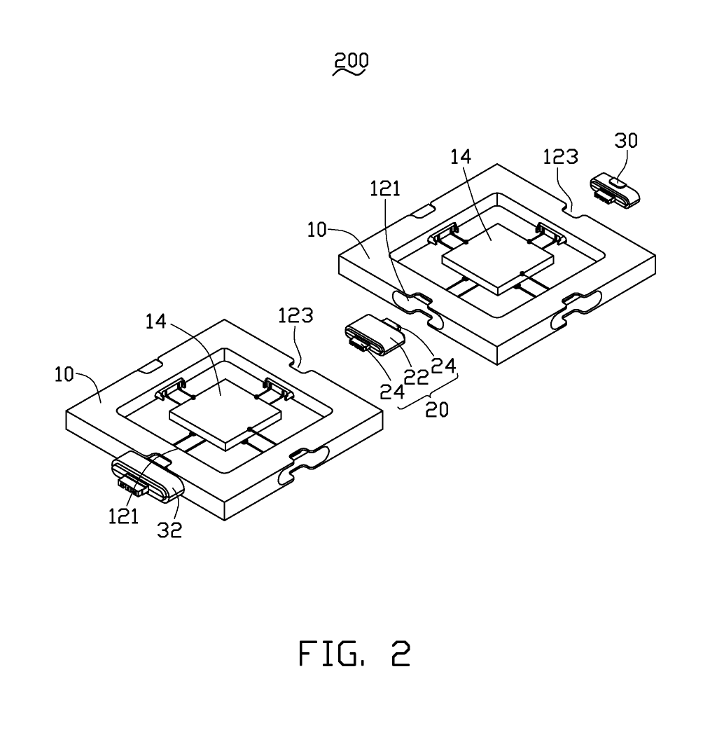

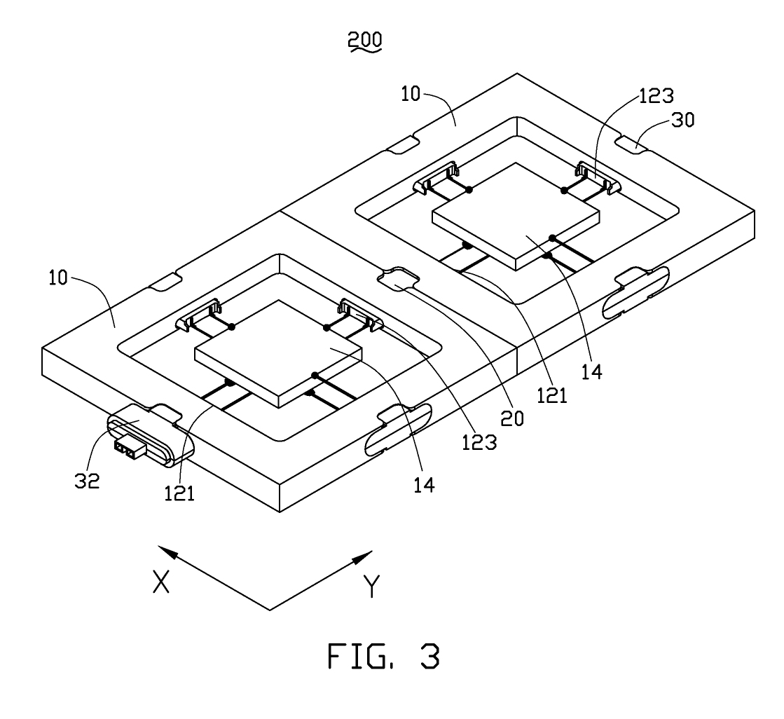

FIGS. 2 and 3 show a solar battery device 200 in accordance with a first embodiment. The solar battery device 200 includes two photovoltaic cells 10, a series interconnector 20 and an end connector 30. The photovoltaic cells 10 are located in line along a Y axis direction, and are designated as a front photovoltaic cell 10 and a rear photovoltaic cell 10. The series interconnector 20 is located between the two photovoltaic cells 10, and electrically connects the two photovoltaic cells 10. The series interconnector 20 includes a main body 22, and two plugs 24 respectively extending outwardly from two opposite sides of the main body 22. The plugs 24 are smaller than the main body 22, and are designated as a front plug 24 and a rear plug 24. The front plug 24 and a front portion of the main body 22 of the series interconnector 20 are received in the second series socket 123 of the front photovoltaic cell 10, and the rear plug 24 and a rear portion of the main body 22 of the series interconnector 20 are received in the first series socket 121 of the rear photovoltaic cell 10. Thereby, the series interconnector 20 electrically connects the first electrical terminal 123a of the second series socket 123 of the front photovoltaic cell 10 with the first electrical terminal 121a of the first series socket 121 of the rear photovoltaic cell 10, and electrically connects the second electrical terminal 123b of the second series socket 123 of the front photovoltaic cell 10 with the second electrical terminal 121b of the first series socket 121 of the rear photovoltaic cell 10.

The shape and size of the end connector 30 match the second series socket 123 of the rear photovoltaic cell 10, such that the end connector 30 is able to fittingly engage with the second series socket 123 of the rear photovoltaic cell 10. In assembly, the end connector 30 is received in the second series socket 123 of the rear photovoltaic cell 10, and electrically connects the first and second electrical terminals 123a, 123b of the second series socket 123 of the rear photovoltaic cell 10 together.

In each of the photovoltaic cells 10, the first electrical terminal 121a of the first series socket 121 is electrically connected with the first electrode 142 of the chip unit 14 of the photovoltaic cell 10, the first electrical terminal 123a of the second series socket 123 is electrically connected with the second electrode 144 of the chip unit 14, and the second electrical terminal 121b of the first series socket 121 is directly electrically connected with the second electrical terminal 123b of the second series socket 123. Accordingly, due to the presence of the series interconnector 20 and the end connector 30, a series connection between the photovoltaic cells 10 is formed in the solar battery device 200. Thus, a voltage of the solar battery device 200 can be outputted through the first and second electrical terminals 121a, 121b of the first series socket 121 of the front photovoltaic cell 10.

In operation, an output connector 32 can be provided to be received in the first series socket 121 of the front photovoltaic cell 10 to output the voltage of the solar battery device 200. In this embodiment, the shape and size of the output connector 32 are substantially the same as those of the series interconnector 20. Alternatively, the output connector 32 can have a shape or size different from that of the series interconnector 20.

In this embodiment, the solar battery device 200 includes two photovoltaic cells 10 electrically connected together in series. Alternatively, the solar battery device 200 can further incorporate more photovoltaic cells 10 therein by utilizing additional series interconnectors 20 for achieving a larger voltage. In that case, the photovoltaic cells 10 are electrically connected together one by one through the series interconnectors 20, with the second series socket 123 of each forward photovoltaic cell 10 connected with the first series socket 121 of an adjacent rearward photovoltaic cell 10. Thereby, a series connection between the photovoltaic cells 10 is formed. The second series socket 123 of the rearmost photovoltaic cell 10 receives the end connector 30, to thereby complete the assembly of the series connected photovoltaic cells 10.

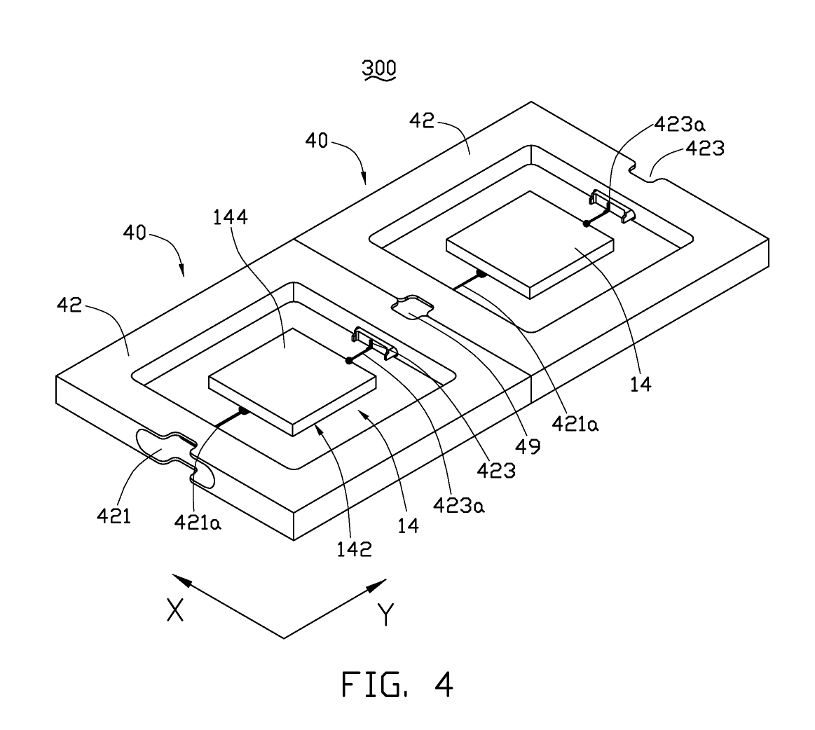

FIG. 4 shows a solar battery device 300 in accordance with a second embodiment. The solar battery device 300 includes two photovoltaic cells 40 electrically connected together by a series interconnector 49. The two photovoltaic cells 40 have the same shape and structure. The photovoltaic cells 40 are located in line along the Y axis direction, and are designated as a front photovoltaic cell 40 and a rear photovoltaic cell 40. Each photovoltaic cell 40 has a configuration similar to the above-described photovoltaic cell 10. In particular, the photovoltaic cell 40 includes a base 42 for supporting the chip unit 14. The photovoltaic cell 40 differs from the photovoltaic cell 10 as follows. The base 42 of each photovoltaic cell 40 includes only a pair of first and second series sockets 421, 423. The first series socket 421 includes only one electrical terminal 421 a therein, and the second series socket 423 includes only one electrical terminal 423a therein. The electrical terminals 421a, 423a are electrically connected with the first and second electrodes 142, 144 of the chip unit 14, respectively.

The series interconnector 49 has a shape the same as the series interconnector 20 of the solar battery device 200 of the first embodiment. The series interconnector 49 engages with the second series socket 423 of the front photovoltaic cell 40, and engages with the first series socket 421 of the rear photovoltaic cell 40. The series interconnector 49 electrically connects the electrical terminal 423a of the second series socket 423 of the front photovoltaic cell 40 with the electrical terminal 421a of the first series socket 421 of the rear photovoltaic cell 40. Thus, the second electrode 144 of the front photovoltaic cell 40 is electrically connected with the first electrode 142 of the rear photovoltaic cell 40. Accordingly, a series connection is formed between the photovoltaic cells 40. In addition, a voltage of the solar battery device 300 can be outputted from both the electrical terminal 421a of the first series socket 421 of the front photovoltaic cell 40 and the electrical terminal 423a of the second series socket 423 of the rear photovoltaic cell 40.

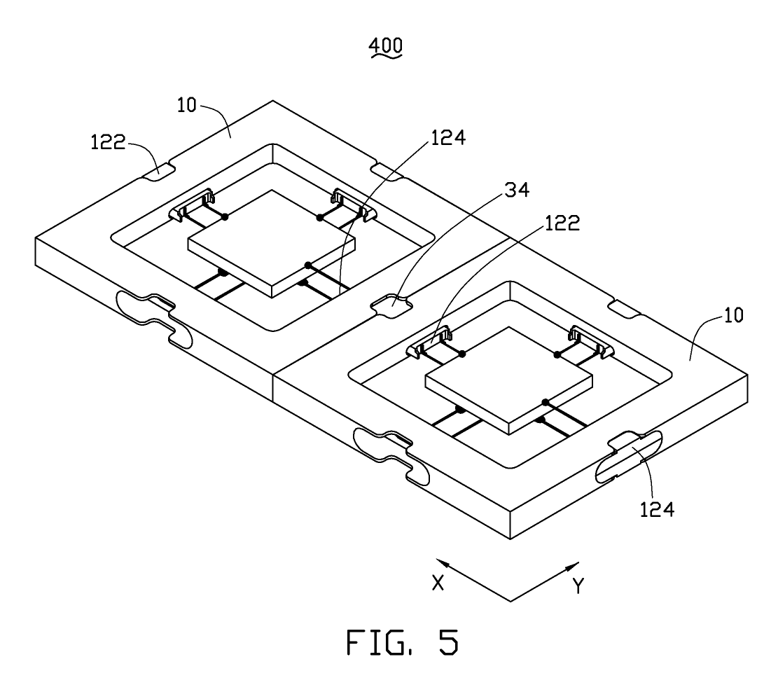

Referring to FIG. 5, a solar battery device 400 in accordance with a third embodiment is shown. The solar battery device 400 includes two photovoltaic cells 10 connected in parallel. The photovoltaic cells 10 are located in line along an X axis direction, and are designated as a front photovoltaic cell 10 and a rear photovoltaic cell 10. The photovoltaic cells 10 are connected with each other by a parallel interconnector 34. In this embodiment, the parallel interconnector 34 is the same as the series interconnector 20 of the solar battery device 200 of the first embodiment. The solar battery device 400 differs from the solar battery device 200 of the first embodiment as follows. The parallel interconnector 34 engages with the first parallel socket 122 of the front photovoltaic cell 10, and engages with the second parallel socket 124 of the rear photovoltaic cell 10, to thereby electrically connect the first parallel socket 122 of the front photovoltaic cell 10 with the second parallel socket 124 of the rear photovoltaic cell 10. Thus, the first electrical terminal 122a of the first parallel socket 122 of the front photovoltaic cell 10 is electrically connected with the first electrical terminal 124a of the second parallel socket 124 of the rear photovoltaic cell 10, and the second electrical terminal 122b of the first parallel socket 122 of the front photovoltaic cell 10 is electrically connected with the second electrical terminal 124b of the second parallel socket 124 of the rear photovoltaic cell 10.

In each of the photovoltaic cells 10, the first and second electrical terminals 122a, 122b of the first parallel socket 122 are respectively electrically connected with the first and second electrodes 142, 144 of the chip unit 14, and the first and second electrical terminals 124a, 124b of the second parallel socket 124 are respectively electrically connected with the first and second electrodes 142, 144 of the chip unit 14. Accordingly, due to the presence of the parallel interconnector 34, the first electrodes 142 of the two photovoltaic cells 10 are electrically connected, and the second electrodes 144 of the two photovoltaic cells 10 are electrically connected, whereby a parallel connection between the photovoltaic cells 10 is formed in the solar battery device 400. A voltage of the solar battery device 400 can be outputted through the first and second electrical terminals 122a, 122b of the first parallel socket 122 of the rear photovoltaic cell 10, or through the first and second electrical terminals 124a, 124b of the second parallel socket 124 of the front photovoltaic cell 10.

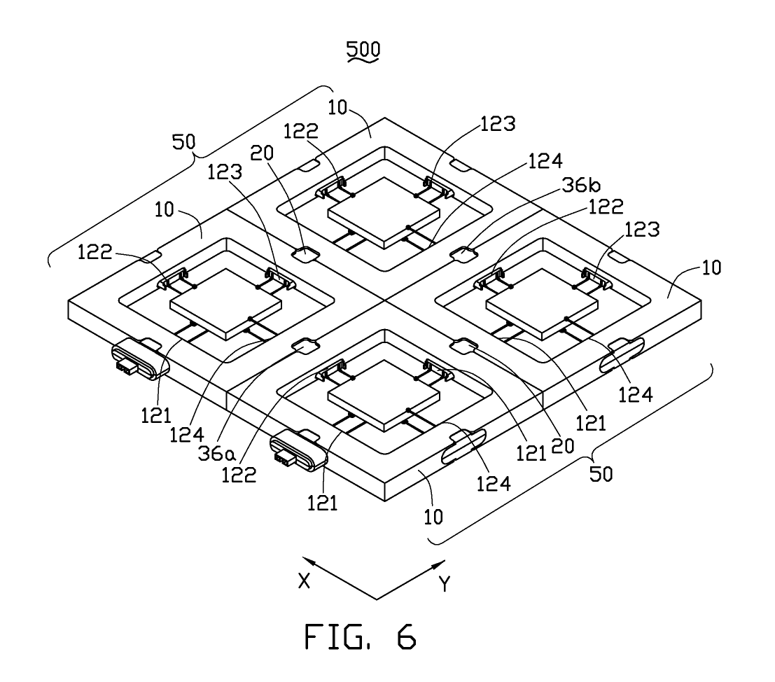

FIG. 6 shows a solar battery device 500 in accordance with a fourth embodiment. The solar battery device 500 includes two series-connected cell sets 50 connected with each other by a first parallel interconnector 36a and a second parallel interconnector 36b. Each of the series-connected cell sets 50 includes two photovoltaic cells 10 arranged in line along the Y axis direction. Actually, each series-connected cell set 50 is essentially the same as the solar battery device 200 of the first embodiment. That is, the photovoltaic cells 10 of each series-connected cell set 50 are electrically connected in series. The two series-connected cell sets 50 are arranged in parallel with each other. The front photovoltaic cell 10 of one series-connected cell set 50 is located adjacent to the front photovoltaic cell 10 of the other series-connected cell set 50, with the first parallel socket 122 of one front photovoltaic cell 10 facing toward the second parallel socket 124 of the other front photovoltaic cell 10. The rear photovoltaic cell 10 of one series-connected cell set 50 is located adjacent to the rear photovoltaic cell 10 of the other series-connected cell set 50, with the first parallel socket 122 of one rear photovoltaic cell 10 facing toward the second parallel socket 124 of the other rear photovoltaic cell 10.

The parallel interconnectors 36a, 36b each have a shape the same as the parallel interconnector 34 of the third embodiment, but differ from the parallel interconnector 34 as follows. The first parallel interconnector 36a is used to only connect the first electrical terminal 122a of the first parallel socket 122 of one photovoltaic cell 10 with the first electrical terminal 124a of the second parallel socket 124 of an adjacent photovoltaic cell 10. The second parallel interconnector 36b is used to only connect the second electrical terminal 122b of the first parallel socket 122 of one photovoltaic cell 10 with the second electrical terminal 124b of the second parallel socket 124 of an adjacent photovoltaic cell 10.

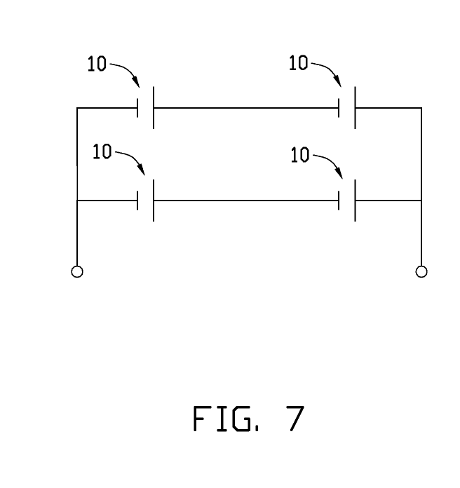

In this embodiment, the first parallel interconnector 36a is arranged between the front photovoltaic cells 10 of the two series-connected cell sets 50, and electrically connects the first parallel socket 122 of one front photovoltaic cell 10 with the second parallel socket 124 of the other front photovoltaic cell 10. Hence, the first parallel interconnector 36a connects the first electrical terminal 122a of the one front photovoltaic cell 10 to the first electrical terminal 124a of the other front photovoltaic cell 10, to thereby electrically connect the first electrodes 142 of the two front photovoltaic cells 10 together. Similarly, the second parallel interconnector 36b is arranged between the rear photovoltaic cells 10 of the two series-connected cell sets 50, and electrically connects the first parallel socket 122 of one rear photovoltaic cell 10 with the second parallel socket 124 of the other rear photovoltaic cell 10. Hence, the second parallel interconnector 36b connects the second electrical terminal 122b of the one rear photovoltaic cell 10 to the second electrical terminal 124b of the other rear photovoltaic cell 10, to thereby electrically connect the second electrodes 144 of the two rear photovoltaic cells 10 together. Thus, the two series-connected cell sets 50 are electrically connected in parallel. FIG. 7 shows an equivalent circuit of the solar battery device 500.

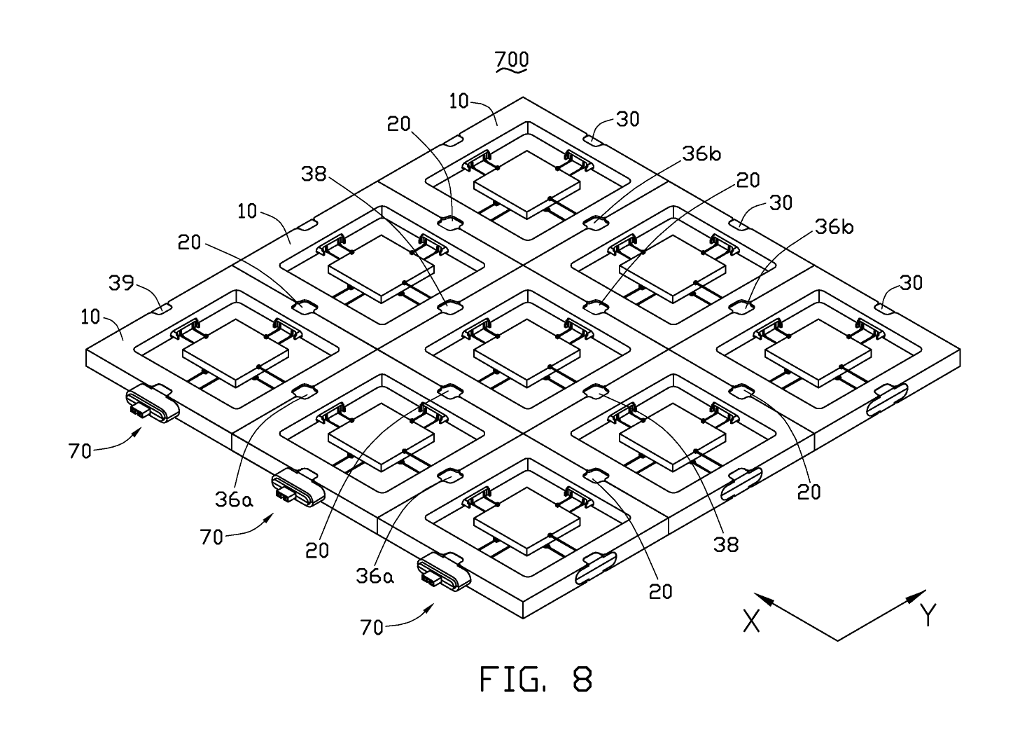

FIG. 8 shows a solar battery device 700 in accordance with a fifth embodiment. The solar battery device 700 is similar to the solar battery device 500 of the fourth embodiment, but incorporates five more photovoltaic cells 10. The solar battery device 700 includes three series-connected cell sets 70, two first parallel interconnectors 36a, two second parallel interconnectors 36b, and two mechanical interconnectors 38.

Each of the series-connected cell sets 70 is similar to each series-connected cell set 50 of the fourth embodiment, but differs from the series-connected cell set 50 in that the series-connected cell set 70 includes three photovoltaic cells 10. In each of the series-connected cell sets 70, the photovoltaic cells 10 are electrically connected in series by two series interconnectors 20 and an end connector 30. More specifically, the photovoltaic cells 10 are electrically connected one by one through the series interconnectors 20, with the second series socket 123 of a forward photovoltaic cell 10 connected with the first series socket 121 of an adjacent rearward photovoltaic cell 10. Thereby, a series connection between the photovoltaic cells 10 is formed. The second series socket 123 of the rearmost photovoltaic cell 10 receives the end connector 30, to thereby complete the assembly of the series connected photovoltaic cells 10.

The series-connected cell sets 70 are arranged parallel with each other, with the foremost photovoltaic cells 10 of the series-connected cell sets 70 located in line along the X axis, the middle photovoltaic cells 10 of the series-connected cell sets 70 located in line along the X axis, and the rearmost photovoltaic cells 10 of the series-connected cell sets 70 located in line along the X axis.

The foremost photovoltaic cells 10 of the series-connected cell sets 70 are electrically connected one by one via the first parallel interconnectors 36a, with the first parallel socket 122 of the foremost photovoltaic cell 10 of one series-connected cell set 70 electrically connected with the second parallel socket 124 of the foremost photovoltaic cell 10 of an adjacent series-connected cell set 70. Thereby, the first electrodes 142 of the foremost photovoltaic cells 10 of the series-connected cell sets 70 are electrically connected together. Similarly, the rearmost photovoltaic cells 10 of the series-connected cell sets 70 are electrically connected one by one via the second parallel interconnectors 36b, with the first parallel socket 122 of the rearmost photovoltaic cell 10 of one series-connected cell set 70 electrically connected with the second parallel socket 124 of the rearmost photovoltaic cell 10 of an adjacent series-connected cell set 70. Thereby, the second electrodes 144 of the rearmost photovoltaic cells 10 of the series-connected cell sets 70 are electrically connected together. Thus, the series-connected cell sets 70 are electrically connected in parallel by the parallel interconnectors 36a, 36b.

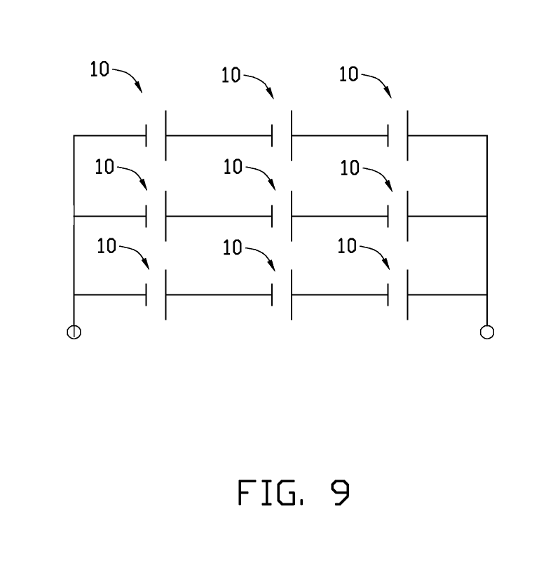

Each mechanical interconnector 38 has a shape the same as the series interconnector 20, but differs from the series interconnector 20 in that the mechanical interconnector 38 is only used to mechanically connect two photovoltaic cells 10 together. The mechanical interconnector 38 connects the first parallel socket 122 of the middle photovoltaic cell 10 of one series-connected cell set 70 with the second parallel socket 124 of the middle photovoltaic cell 10 of an adjacent series-connected cell set 70. Thereby, the middle photovoltaic cells 10 of the series-connected cell sets 70 are mechanically connected one by one via the mechanical interconnectors 38, and a mechanical strength of the solar battery device 700 is increased. FIG. 9 shows an equivalent circuit of the solar battery device 700.

In addition, stoppers 39 can be provided to seal the unused sockets of the photovoltaic cells 10, thereby mechanically and electrically protecting the photovoltaic cells 10. Each stopper 39 has a shape corresponding to that of the end connector 30, but differs from the end connector 30 as follows. When the stopper 39 is installed in an unused socket, the stopper 39 is flush with a top surface of the base 12, a lateral side surface of the base 12, and a bottom surface of the base 12. In addition, the stopper 39 is unable to electrically connect the first and second electrical terminals of the unused socket.

Each of the solar battery devices 500, 700 includes a plurality of separate photovoltaic cells 10 electrically and mechanically connected with each other by connectors, which makes the solar battery devices 500, 700 easy to assemble and disassemble. If a photovoltaic cell 10 of the solar battery device 500 or 700 is faulty or broken, it is convenient to replace the photovoltaic cell 10 and thereby restore the solar battery device 500 or 700.

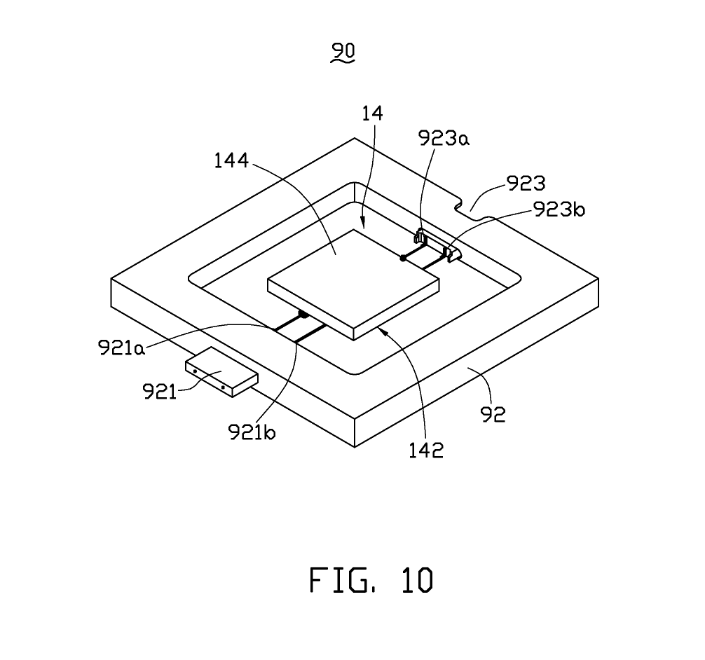

FIG. 10 shows a photovoltaic cell 90 in accordance with various alternative embodiments of a solar battery device herein. The photovoltaic cell 90 has a configuration similar to the photovoltaic cell 10 of the first embodiment. In particular, the photovoltaic cell 90 includes a base 92 for supporting the chip unit 14. The photovoltaic cell 90 differs from the photovoltaic cell 10 of the first embodiment as follows. The base 92 of the photovoltaic cell 90 forms a first electrical connector 921 and a second electrical connector 923. In this embodiment, the first electrical connector 921 is in the form of a plug, and the second electrical connector 923 is in the form of a socket. The first electrical connector 921 protrudes outwardly from one side of an outer periphery of the base 92. The second electrical connector 923 is defined at an opposite side of the outer periphery of the base 92. A shape and a size of the first electrical connector 921 match the second electrical connector 923, whereby the first electrical connector 921 of one photovoltaic cell 90 can fittingly engage with the second electrical connector 923 of a neighboring photovoltaic cell 90.

The first electrical connector 921 includes a first electrical terminal 921a and a second electrical terminal 921b therein, and the second electrical connector 923 includes a first electrical terminal 923a and a second electrical terminal 923b therein. The first electrical terminal 921 a is electrically connected with the first electrode 142 of the chip unit 14. The first electrical terminal 923a is electrically connected with the second electrode 144 of the chip unit 14. The second electrical terminal 921b is directly electrically connected with the second electrical terminal 923b.

When a plurality of the photovoltaic cells 90 are assembled together in series, the first electrical connector 921 of one photovoltaic cell 90 engages with the second electrical connector 923 of an adjacent photovoltaic cell 90, and the first and second electrical terminals 921a, 921b of the first electrical connector 921 of the one photovoltaic cell 90 respectively electrically connect with the first and second electrical terminals 923a, 923b of the second electrical connector 923 of the adjacent photovoltaic cell 90. Thereby, the photovoltaic cells 90 are mechanically and electrically connected together. In this embodiment, the photovoltaic cells 90 can be connected with each other without the need for separate series interconnectors, such that the solar battery device can have a lower cost.

It is to be understood, however, that even though numerous characteristics and advantages of the exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A solar battery device, comprising:
a plurality of photovoltaic cells detachably connected together, each photovoltaic cell comprising a base and a chip unit supported by the base;
the chip unit comprising a first electrode at a bottom thereof and a second electrode at a top thereof; and
the base comprising at least one first electrical terminal and at least one second electrical terminal, each of the at least one first electrical terminal electrically connected with the first electrode of the chip unit, and each of the at least one second electrical terminal electrically connected with the second electrode of the chip unit, the photovoltaic cells electrically connected with each other in a selected one of the following arrangements: connection in series, connection in parallel, and connection in both series and parallel, via corresponding ones of the at least one first electrical terminal and at least one second electrical terminal.

2. The solar battery device of claim 1, comprising at least two of the photovoltaic cells connected in series, with one of the at least one second electrical terminal of a forward photovoltaic cell being connected with one of the at least one first electrical terminal of an adjacent rearward photovoltaic cell.

3. The solar battery device of claim 2, wherein each photovoltaic cell further comprises a first series electrical connector and a second series electrical connector, the one of the at least one first electrical terminal is located in the first series electrical connector, and the one of the at least one second electrical terminal is located in the second series electrical connector.

4. The solar battery device of claim 3, further comprising at least one series interconnector, wherein each of the first and second series electrical connectors of each photovoltaic cell is in the form of a socket, each of the at least one series interconnector engages with the second series electrical connector of a corresponding forward photovoltaic cell and engages with the first series electrical connector of the corresponding adjacent rearward photovoltaic cell to thereby electrically connect the second electrical terminal of the corresponding forward photovoltaic cell with the first electrical terminal of the corresponding adjacent rearward photovoltaic cell.

5. The solar battery device of claim 4, wherein each photovoltaic cell further comprises a third electrical terminal and a fourth electrical terminal respectively located in the first and second series electrical connectors, the third electrical terminal and the fourth electrical terminal of each photovoltaic cell are electrically connected with each other, the fourth electrical terminal of the corresponding forward photovoltaic cell is electrically connected with the third electrical terminal of the corresponding adjacent rearward photovoltaic cell by the series interconnector, and the second electrical terminal and the fourth electrical terminal in the second series electrical connector of the rearmost photovoltaic cell are electrically connected together.

6. The solar battery device of claim 5, further comprising an end connector received in the second series electrical connector of the rearmost photovoltaic cell, wherein the second electrical terminal and the fourth electrical terminal in the second series electrical connector of the rearmost photovoltaic cell are electrically connected together by the end connector.

7. The solar battery device of claim 2, comprising a plurality of series-connected cell sets, wherein the at least one first electrical terminal of the base of each photovoltaic cell comprises at least three first electrical terminals, the at least one second electrical terminal of the base of each photovoltaic cell comprises at least three second electrical terminals, each series-connected cell set comprises at least two of the photovoltaic cells connected in series with one of the second electrical terminals of a forward photovoltaic cell electrically connected with one of the first electrical terminals of an adjacent rearward photovoltaic cell, the series-connected cell sets are connected in parallel, with a first another one of the first electrical terminals of the foremost photovoltaic cell of each series-connected cell set electrically connected with a second another one of the first electrical terminals of the foremost photovoltaic cell of an adjacent series-connected cell set, and with a first another one of the second electrical terminals of the rearmost photovoltaic cell of each series-connected cell set electrically connected with a second another one of the second electrical terminals of the rearmost photovoltaic cell of the adjacent series-connected cell set.

8. The solar battery device of claim 7, further comprising a plurality of series interconnectors, wherein in each series-connected cell set, the photovoltaic cells are connected in series one by one through at least one of the series interconnectors, each photovoltaic cell further comprises a first series electrical socket and a second series electrical socket, the one of the first electrical terminals and the one of the second electrical terminals of the photovoltaic cell are located in the first and second series electrical sockets, respectively, and each of the at least one series interconnector engages with the second series electrical socket of a corresponding forward photovoltaic cell and engages with the first series electrical socket of the corresponding adjacent rearward photovoltaic cell to thereby electrically connect the one of the second electrical terminals of the corresponding forward photovoltaic cell with the one of the first electrical terminals of the corresponding adjacent rearward photovoltaic cell.

9. The solar battery device of claim 8, further comprising at least one first parallel interconnector and at least one second parallel interconnector, wherein each of the at least one first parallel interconnector electrically connects the first another one of the first electrical terminals of the foremost photovoltaic cell of one series-connected cell set with the second another one of the first electrical terminals of the foremost photovoltaic cell of the adjacent series-connected cell set, and each of the at least one second parallel interconnector electrically connects the first another one of the second electrical terminals of the rearmost photovoltaic cell of one series-connected cell set to the second another one of the second electrical terminals of the rearmost photovoltaic cell of the adjacent series-connected cell set, to thereby electrically connect the series-connected cell sets in parallel.

10. The solar battery device of claim 9, wherein each photovoltaic cell further comprises a first parallel electrical socket and a second parallel electrical socket, the first another one of the first electrical terminals and the first another one of the second electrical terminals are both formed in the first parallel electrical socket, the second another one of the first electrical terminals and the second another one of the second electrical terminals are both formed in the second parallel electrical socket, each of the at least one first parallel interconnector engages with the first parallel electrical socket of the foremost photovoltaic cell of one series-connected cell set and engages with the second parallel electrical socket of the foremost photovoltaic cell of an adjacent series-connected cell set, and each of the at least one second parallel interconnector engages with the first parallel electrical socket of the rearmost photovoltaic cell of one series-connected cell set and engages with the second parallel electrical socket of the rearmost photovoltaic cell of an adjacent series-connected cell set.

11. The solar battery device of claim 10, further comprising at least one mechanical interconnector, wherein each series-connected cell set comprises at least three photovoltaic cells, each of the at least one mechanical interconnector engages with the first parallel electrical socket of an intermediate photovoltaic cell of one series-connected cell set and engages with the second parallel electrical socket of a corresponding intermediate photovoltaic cell of an adjacent series-connected cell set to mechanically connect the corresponding intermediate photovoltaic cells of the series-connected cell sets together.

12. The solar battery device of claim 1, comprising at least two of the photovoltaic cells connected in parallel, wherein each photovoltaic cell further comprises a first parallel electrical connector and a second parallel electrical connector, the at least one first electrical terminal comprises at least two first electrical terminals, the at least one second electrical terminal comprises at least two second electrical terminals, one of the first electrical terminals and one of the second electrical terminals are both formed in the first parallel electrical connector, another one of the first electrical terminals and another one of the second electrical terminals are both formed in the second parallel electrical connector, and the first parallel electrical connector of each forward photovoltaic cell is electrically connected with the second parallel electrical connector of the corresponding adjacent rearward photovoltaic cell, with the first electrical terminal of the first parallel electrical connector of the forward photovoltaic cell electrically connected with the first electrical terminal of the second parallel electrical connector of the adjacent rearward photovoltaic cell, and with the second electrical terminal of the first parallel electrical connector of the forward photovoltaic cell electrically connected with the second electrical terminal of the second parallel electrical connector of the adjacent rearward photovoltaic cell, whereby the photovoltaic cells are electrically connected in parallel.

13. The solar battery device of claim 12, further comprising at least one parallel interconnector, wherein each of the first and second parallel electrical connectors of each photovoltaic cell is in the form of a socket, each of the at least one parallel interconnector engages with the first parallel electrical connector of a corresponding forward photovoltaic cell and engages with the second parallel electrical connector of the corresponding adjacent rearward photovoltaic cell, to electrically connect the first electrical terminal of the first parallel electrical connector of the corresponding forward photovoltaic cell with the first electrical terminal of the second parallel electrical connector of the corresponding adjacent rearward photovoltaic cell, and electrically connect the second electrical terminal of the first parallel electrical connector of the corresponding forward photovoltaic cell with the second electrical terminal of the second parallel electrical connector of the corresponding adjacent rearward photovoltaic cell.

14. The solar battery device of claim 1, wherein each photovoltaic cell further comprises a first series electrical connector and a second series electrical connector at two opposite sides thereof, respectively, and a first parallel electrical connector and a second parallel electrical connector at another two opposite sides thereof, respectively, the at least one first electrical terminal comprises at least three first electrical terminals, the at least one second electrical terminal comprises at least three second electrical terminals, one of the first electrical terminals is formed in the first series electrical connector and one of the second electrical terminals is formed in the second series electrical connector, a first another one of the first electrical terminals and a first another one of the second electrical terminals are both formed in the first parallel electrical connector, and a second another one of the first electrical terminals and a second another one of the second electrical terminals are both formed in the second parallel electrical connector.

15. The solar battery device of claim 14, further comprising at least one stopper, wherein each of the first and second series electrical connectors of each photovoltaic cell is in the form of a socket, each of the first and second parallel electrical connectors of each photovoltaic cell is in the form of a socket, and each of the at least one stopper is engaged in a corresponding unused socket to protect the unused socket.

16. The solar battery device of claim 1, wherein each photovoltaic cell further comprises a first electrical connector and a second electrical connector, the first electrical connector is in the form of a plug, the second electrical connector is in the form of a socket, the at least one first electrical terminal is one first electrical terminal, the at least one second electrical terminal is one second electrical terminal, the first electrical terminal is located in the first electrical connector, and the second electrical terminal is located in the second electrical connector, the first electrical connector of one photovoltaic cell engaging in the second electrical connector of a corresponding adjacent photovoltaic cell to electrically connect the first electrical terminal with the second electrical terminal.

17. The solar battery device of claim 1, wherein each photovoltaic cell further comprises an encapsulating layer encapsulating the chip unit thereof.

18. The solar battery device of claim 17, wherein the base of each photovoltaic cell defines a recess at a top thereof, the recess receiving the chip unit therein.

19. A solar battery device, comprising:
a plurality of photovoltaic cells detachably connected together, each photovoltaic cell comprising a base and a chip unit supported by the base;
the chip unit comprising a first electrode at a bottom thereof and a second electrode at a top thereof; and
the base comprising a first series electrical connector and a second series electrical connector, a first electrical terminal located in the first series electrical connector, a second electrical terminal located in the second series electrical connector, the first and second electrical terminals electrically connected with the first and second electrodes of the chip unit, respectively;
the photovoltaic cells electrically connected in series, with the second electrical terminal of each forward photovoltaic cell electrically connected with the first electrical terminal of a corresponding adjacent rearward photovoltaic cell.

20. The solar battery device of claim 19, comprising a plurality of series-connected cell sets, each series-connected cell set comprising at least two of the photovoltaic cells connected in series, wherein each photovoltaic cell further comprises another two first electrical terminals and another two second electrical terminals, the series-connected cell sets are connected in parallel with one of the another two first electrical terminals of the foremost photovoltaic cell of one series-connected cell set electrically connected with the other one of the another two first electrical terminals of the foremost photovoltaic cell of an adjacent series-connected cell set, and with one of the another two second electrical terminals of the rearmost photovoltaic cell of the one series-connected cell set electrically connected with the other one of the another two second electrical terminals of the rearmost photovoltaic cell of the adjacent series-connected cell set.
